(19) United States
(12) Patent Application Publication
(10) Pub. No.: US 2014/0088972 A1
(43) Pub. Date: Mar. 27, 2014

(54) ENVELOPE WITH RECORDABLE AUDIO MEDIUM

(71) Applicant: Dinotalk, Inc., Alpharetta, GA (US)

(72) Inventor: Bart Gentiel Vantieghem, Alpharetta, GA (US)

(73) Assignee: Dinotalk, Inc., Alpharetta, GA (US)

(21) Appl. No.: 14/091,416

(22) Filed: Nov. 27, 2013

Related U.S. Application Data
(63) Continuation of application No. 12/145,752, filed on Jun. 25, 2008, now abandoned.

(51) Int. Cl. G11C 16/22; G10L 21/00

(52) U.S. Cl. CPC G11C 16/225; G10L 21/00
USPC 704/272

(57) ABSTRACT

An article carrier, such as an envelope for holding and presenting an article such as a gift card, includes an electronic device allowing for recording and re-recording of an audio stream or message to accompany the article. The electronic device includes a removable or breakable portion so that the recording may be locked to prevent re-recording.

### CROSS-REFERENCE TO RELATED APPLICATIONS

The present application is a continuation of U.S. patent application Ser. No. 12/145,752 filed on Jun. 25, 2008, the entire disclosure of which is incorporated herein by reference.

### FIELD OF THE INVENTION

The invention relates to an envelope having a recordable medium and, in particular, to an envelope having internal components for recording and playback of audio, the internal components adapted to prevent overwriting of the recorded audio.

### BACKGROUND OF THE INVENTION

Electronic components and circuits continue to benefit from increases in technology that result in decreases in costs. Due to the decreases in costs, it has become known to incorporate simple electronic devices even in applications that are generally considered disposable.

As an example, it is not uncommon to find greeting cards including a small electronic device for playing audio, the device activated by opening the card. The components of the device are generally secured on one side of the card, and an actuator portion is secured across a fold from the one side to a second side. The actuator portion has a fold formed therein so that, when the card is closed, the portion on the one side moves to an “off” position, yet opening of the card straightens the actuator portion and pulls the same to an “on” position, thus activating the device to play the re-recorded audio.

Some greeting cards are clearly not personal to the recipient. For instance, the commercial airline company Southwest Airlines provides customers enrolled in the company's frequent flier program with a greeting card on their birthday. As another example, State Farm Insurance has traditionally done the same. However, without anything more than a clearly pre-printed message and no real signature, the impact of such an impersonal card is diminished.

Greeting cards from friends and relatives typically convey a greater sense of personalization, as well as a greater sense of fun and enjoyment. Accordingly, cards that include the above described audio-playback circuit are found desirable. The giver of such greeting cards will also spend more time and effort in selecting a card that is appropriate to the relationship between the giver and the recipient, considering a number of features including the pre-printed message, the artwork or theme which may be humorous or emotionally touching, as examples, as well as the actual message for any card including the above-described audio playback.

U.S. Pat. No. 5,761,836, to Dawson, discloses a “card” as a “presentation vehicle” for a gift or article. A slot is provided in the card for receiving the article so that insertion of the article opens a circuit, and removal of the article closes the circuit to activate audio playback of a message. The card also operates as described above so that folding two portions also opens the circuit to de-activate the playback.

U.S. Pat. Nos. 5,387,108 and 5,577,918 are related patents to Crowell that disclose a variety of designs that can record a user's personalized audio message and play the same when activated. In the disclosed designs, it is considered an important feature that the device allows recording and re-recording of the audio message.

Accordingly, there has been a need for an improved article for carrying an audio playback device having a user recordable medium.

### SUMMARY OF THE INVENTION

In accordance with an aspect, an article carrier is disclosed comprising a body having a foldably movable portion and adapted to receive an article therein, and an electronic device positioned within the body, the electronic device including a power source for powering the electronic device, a storage medium for storing an input audio stream thereon as a recording, a record actuator for recording the input audio stream to the storage medium, a movable component having a playback position for activating a playback of the recording, the movable component coupled with the body movable portion, and a breakpoint for disconnecting the record actuator and preventing overwriting of the recording.

In some forms, the body is a paper blank folded to the form of an envelope. The body movable portion may be an envelope flap. The flap may have a fully opened position, and the movable component playback position generally may correspond to the fully opened position.

In some forms, the breakpoint is located on a circuit between the record actuator and the power source.

In some forms, the storage medium is a re-writeable memory chip. The breakpoint may be located on a circuit between the power source and the record actuator, and the record actuator may be located on the circuit between the storage medium and the breakpoint.

In some forms, the article carrier further includes a tab, wherein the breakpoint is easily broken, and force applied to the tab breaks the breakpoint.

In some forms, the body is adapted to receive a gift card.

In another aspect, a method of providing an article carrier is disclosed including the steps of a providing a body, disposing an electronic device having a storage medium within the body, activating the storage medium to record an audio stream thereon as a recording, and breaking a connection between the storage medium and a power source to lock the recording on the storage medium.

In some forms, the step of providing a body includes providing a paper blank and folding same to the shape of an envelope.

In some forms, the method further includes, prior to the step of breaking the connection, the steps of playing the recording, deciding whether the recording is to be overwritten, and, if the recording is to be overwritten, repeating the step of activating the storage medium to record a subsequent audio stream as the recording.

In some forms, the step of activating includes depressing a button. The button may be located within the body, and the button may be activated through the body.

In some forms, the step of breaking includes pulling a tab to break a circuit connection between the storage medium and a power source.

In some forms, the method further includes inserting the article within the body.

In some forms, the method further includes the step of moving a portion of the body in order to activate playing of the recording from the storage medium.

In some forms, the method further includes the step of providing a speaker for playing the audio recording.

### BRIEF DESCRIPTION OF THE DRAWINGS

In the Figures, FIG. 1 is a front elevation view of an article carrier in the form of an envelope with electronic components therein for recording and re-recording of an audio stream, article carrier including a piece in the form of a tab that is removable to lock the recording audio;

FIG. 2 is a front elevation view of the article carrier of FIG. 1 with a body thereof in the form of a paper blank un-folded to expose the electronic components; and

FIG. 3 is a representative block diagram of a circuit of the electronic components of the article carrier of FIG. 1.

### DETAILED DESCRIPTION OF THE INVENTION

Referring to FIGS. 1-3, an article carrier in the form of an envelope 10 capable of playing a user selected audio recording, accidental overwriting of the recording being protected and prevented. As used herein, the term prevented is used to mean stopped or the possibility of being eliminated unless out-of-the ordinary steps are taken. As will be discussed below, in a preferred embodiment, a plurality of envelopes 10 may be provided either generally blank or with a variety of pre-printed graphics, indicia, or artwork printed thereon, a user may select one of the envelopes 10, the user would record an audio recording such as a spoken greeting or user selected music or any other audio recording or combination thereof, the user would lock the recording, and the envelope 10 may then be given as a companion to a gift article such as a gift card or certificate, for instance. In this manner, the envelope 10 allows the user to personalize the giving of a gift card that is not typically considered personal. While gift cards can take many forms, it is common for such to be similar to a credit card, both in terms of size and material as well as a code or account number printed on the card and often encoded on a magnetic strip.

Towards this end, the envelope 10 includes an electronic circuit device 12 including an output component in the form of a speaker 14, a power source in the form of a battery 16, an input component in the form of a microphone 18, and a storage medium in the form of an integrated circuit chip (IC) 20.

In a preferred form, the IC 20 is a re-writeable chip. A user uses the microphone 18 to input an audio stream that becomes the audio recording stored on the IC 20. As the user may, for any reason, be dissatisfied with a first recording, it is desirable to permit the user to change the recording. However, in some forms, it may be desirable to use a write-once integrated circuit.

Initially, the IC 20 is programmed to accept an audio recording. In some forms, the IC 20 may include audio instructions to a user on how to record an audio stream, and such instructions may be overwritten by the user recording their selected audio stream onto the IC 20.

To record a message, a record actuator 26 is provided. In a preferred form, the record actuator 26 is a switch that generally requires some intentional act to activate. For instance, a hole may be provided in a switch housing, and insertion of a pin into the hole depresses a plate to connect the switch and move the record actuator 26 to a closed circuit position that allows recording to the IC 20. However, it is also recognized that it is difficult for a user to manipulate a pin, for instance, and maintain the pin in the hole as is required while also recording a message. To be more specific and as an example, a user may choose to record an audio stream from an audio source such as a television or another speaker (i.e., a speaker other than the speaker 14 carried by the envelope 10), and such may require moving the envelope 10 and microphone 18 to a position proximate the audio source and the record actuator 26 must be held in the closed position during the recording. In order to minimize frustration and maximize ease of actuation for a user, the record actuator 26 is preferably simply in the form of a button 27. In one form, the record actuator 26 may be provided with a removable or frangible protector or cover so that, prior to a first use, the possibility of accidental actuation is minimized, such as compression or jostling that may occur during shipping.

Once an audio stream has been recorded to the IC 20 via the microphone 18, the user may desire to review the recording. Generally, the microphone 18 is positioned as an interior portion of the envelope 10, and the envelope 10 includes a body generally formed of a folded paper blank 30. Therefore, the audio stream may be received by the microphone 18 through the paper 30. The record actuator 26 may be operated through the paper 30, which in some forms may have a small hole aligned with the above-described record actuator housing hole. As the recording may be made without opening the envelope 10, playback of the recording may then be activated by opening an envelope flap 30a in a manner similar to that which is used in prior art audio-playing greeting cards, specifically, but pulling a play tab 36 to activate the IC 20 to provide the recorded audio to an amplifier 40 and the speaker 14.

In other forms, it may be desirable to have the flap 30a opened to an intermediate position in order to record the audio stream, yet calibrate or coordinate the playback to occur when the flap 30a is in a fully-opened position. Advantageously, audio playback is desired when a recipient of the envelope 10 and its contents opens the envelope flap 30a to a position that permits withdrawal of the contents from the envelope 10, which generally requires the flap 30a to be fully-opened. As such, the envelope 10 may be partially opened during recording, with the flap 30a at a less-than-fully-opened position, to improve the clarity of the recording by not requiring the audio stream to pass through the paper 30.

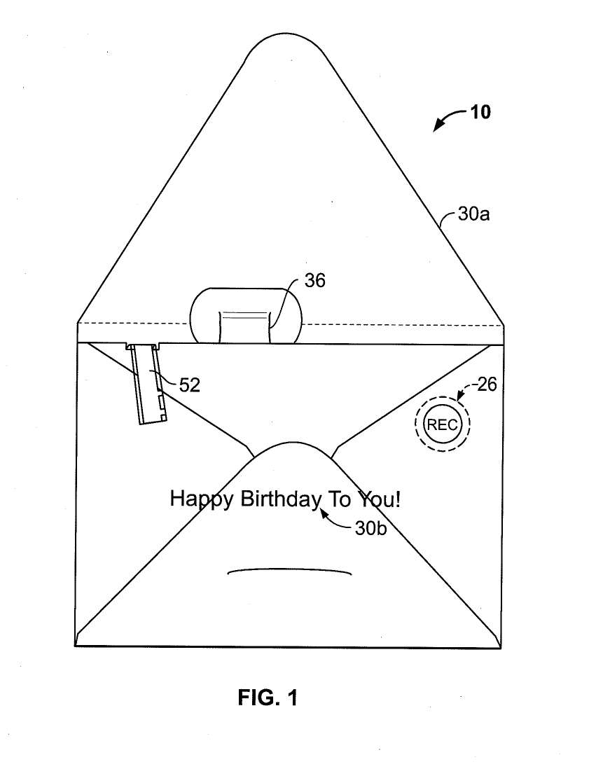

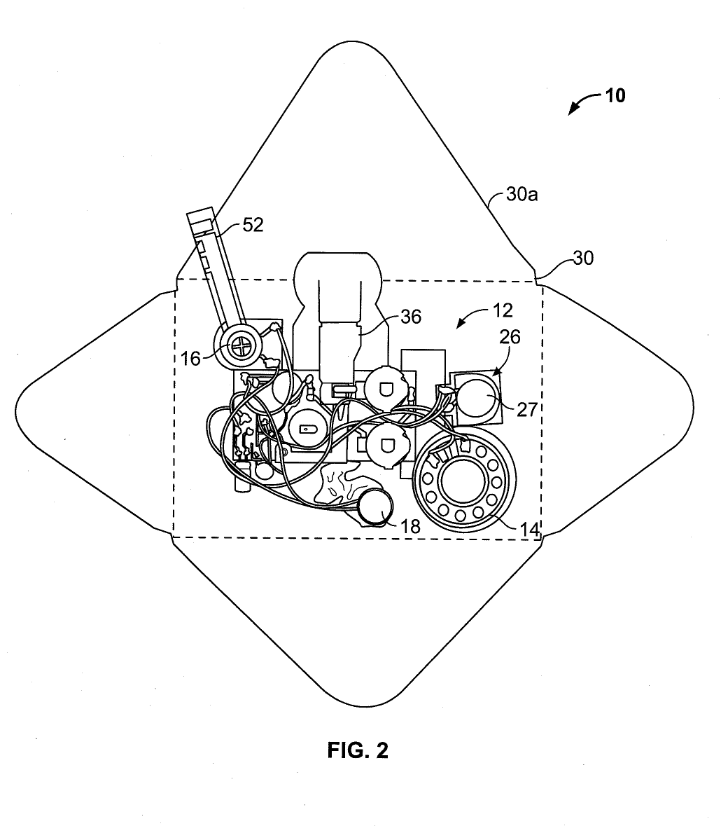

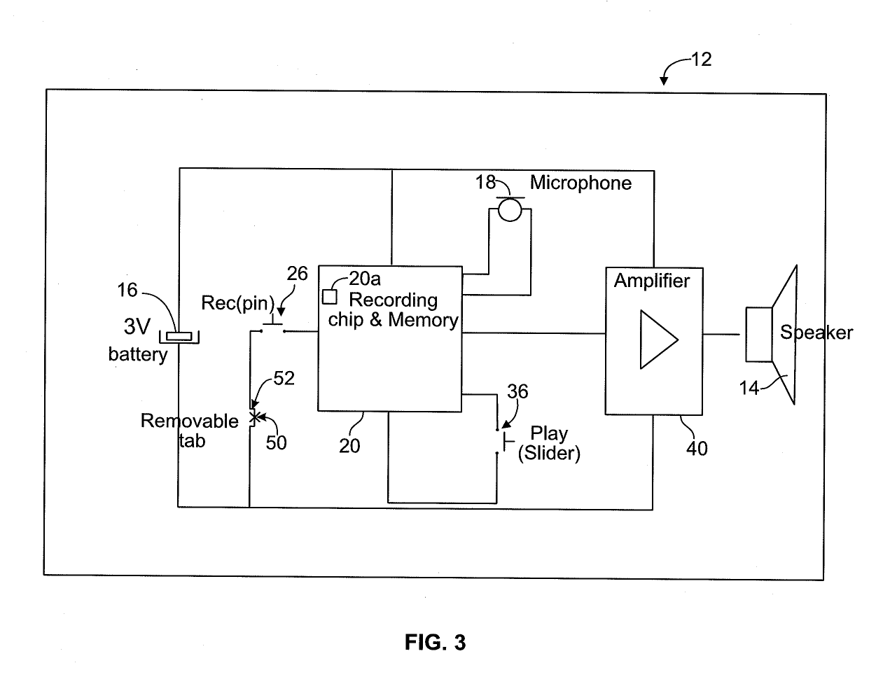

Once the user is satisfied with the recording, such as by reviewing the playback, the user can lock the recording to the IC 20. In the present and preferred form, the user locks the recording by literally breaking the circuit for the record actuator 26. Turning to FIG. 3, a block diagram of the circuit is shown having the battery 16 connected across the IC 20 and across the amplifier 40 that powers the speaker 14. The battery 16 is also connected to one side of the record actuator 26, which is in turn connected on its other side to the IC 20. A breakpoint 50 is provided between the battery 16 and the record actuator 26. In the present form, the breakpoint 50 is connected to a thin strip of material referred to herein as tab 52 (see FIGS. 1 and 2). The tab 52 may be pulled away from the circuit components so that it breaks away from the circuit and is removed entirely from the envelope 10. The record actuator 26 is connected to a pin 20a of the IC 20, as is readily understood, and the break at the breakpoint 50 due to removal of the tab 52 prevents power from reaching the record actuator pin 20a and, thus, the IC 20 cannot be commanded to re-write over whatever audio stream recording is present on the IC 20.

As described then, a user is able to easily use the button 27 to record a message or audio stream to the IC 20, without difficulty that may be experienced with other types of record actuators. Yet, despite the ease of recording by pressing the button 27, the envelope 10 provides the ability to lock the recording on the IC 20, and prevent the accidental overwriting of the recording, by allowing the simple and elegant tab 52 solution for breaking the circuit and preventing power to reach the record actuator pin 20a on the IC 20.

The paper blank 30 may be printed with artwork, graphics, or other surface indicia 30b, though such is minimally illustrated in the Figs. for the sake of ease of understanding.

The present invention in the form of the envelope 10 allows a user to provide a highly personalized gift presentation to a recipient. The user may select an envelope 10 having desirable graphics thereon, such as would generally be provided for a greeting card. The envelope provides an easy-to-use button 27 to record a message or other audio stream to personalize the envelope 10. The breakpoint 50 allows the user to make sure that the ease of the button 27 does not result in accidental or inadvertent overwriting of the recorded audio stream, as well as prevents re-use or ‘re-gifting’ of the envelope 10. The envelope 10 is then able to receive another article therein for presentation as a gift, particularly an article such as a gift card that is generally not considered personal to a recipient.

As a cost comparison, it is believed that a cost for the envelope 10 as described including the paper 30, the electronic components involved, and the assembly thereof, is in the range of approximately $2.00 USD, while the cost of a traditional greeting card at retail is generally $1.75 to $4.00 USD, such that the envelope 10 is competitive with such greeting cards. The cost of a gift card is generally limited to the face or recorded value of the gift card. As such, the envelope 10 can serve the function of the traditional greeting card at a competitive cost and with increased personalization.

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims.

What is claimed is:

1. An article carrier, comprising:
a body having a foldably movable portion and adapted to receive an article therein, wherein the body comprises paper folded in the form of an envelope and wherein the foldably movable portion of the body is a flap of the envelope; and
an electronic device positioned within the body, the electronic device including
a power source for powering the electronic device,
a re-writeable storage medium for storing an input audio stream thereon as a recording provided by an end user,
a record actuator for recording the input audio stream to the re-writeable storage medium,
a movable component having a playback position for activating a playback of the recording provided by the end user and currently stored on the re-writeable storage medium, the movable component coupled with the body movable portion, and
a breakpoint for disconnecting the record actuator and preventing any further overwriting of the recording provided by the end user and now permanently stored on the re-writeable storage medium;
wherein the flap has a fully opened position, and the movable component playback position generally corresponds to the fully opened position.

2. The article carrier of claim 1, wherein the breakpoint is located on a circuit between the record actuator and the power source.

3. The article carrier of claim 1, wherein the storage medium is rewriteable memory chip.

4. The article carrier of claim 1, wherein the breakpoint is located on a circuit between the power source and the record actuator, and the record actuator is located on the circuit between the storage medium and the breakpoint.

5. The article carrier of claim 1, and further including a tab, wherein the breakpoint is easily broken, and force applied to the tab breaks the breakpoint.

6. The article carrier of claim 1, wherein the body is adapted to receive a gift card.

7. The article carrier of claim 1, and further comprising a speaker for playing the recording when the movable component is in the playback position.

8. The article carrier of claim 1, wherein the power source is a battery.

9. The article carrier of claim 1, wherein the storage medium is an integrated circuit chip.

10. The article carrier of claim 1, wherein the record actuator includes a microphone.

11. The article carrier of claim 1, wherein the recorded actuator includes a depressable button for initiating recording of the input audio stream.

12. The article carrier of claim 11, wherein the record actuator continues recording the input audio stream as long as the depressable button remains depressed.

13. The article carrier of claim 12, wherein the record actuator continues recording the input audio stream for a predetermined period of time even if the depressable button remains depressed for longer than the predetermined period of time.

14. The article carrier of claim 11, wherein the record actuator continues recording the input audio stream for a predetermined period of time after the depressable button has been depressed.

15. The article carrier of claim 1, wherein a pre-recorded message is stored in the rewriteable storage medium and the playback position activates a playback of the pre-recorded message.

16. The article carrier of claim 15, wherein the pre-recorded message is over-written by the recording provided by the end user.

17. The article carrier of claim 1, and further comprising a speaker from which the playback of the recording is audible.

18. The article carrier of claim 1, and further comprising an amplifier in electronic communication with the speaker and used to amplify playback of the recording.
